(19) United States
(12) Patent Application Publication
(10) Pub. No.: US 2014/0056052 A1
(43) Pub. Date: Feb. 27, 2014

(54) RESISTIVE MEMORY DEVICE PERFORMING SELECTIVE REFRESH AND METHOD OF REFRESHING RESISTIVE MEMORY DEVICE

(71) Applicant: JUNG-HYUK LEE, YONGIN-SI (KR)

(72) Inventor: JUNG-HYUK LEE, YONGIN-SI (KR)

(21) Appl. No.: 13/925,177

(22) Filed: Jun. 24, 2013

(30) Foreign Application Priority Data
Aug. 23, 2012 (KR) 10-2012-0092614

(51) Int. Cl. G11C 13/00

(52) U.S. Cl. CPC G11C 13/0033
USPC 365/145; 365/148; 365/158

(57) ABSTRACT

A method of operating a resistive memory device, includes; performing a data retention time test on a resistive memory cell array of a memory chip, determining a number of bad memory blocks of the resistive memory cell array on the basis of the data retention time test, determining on the basis of the number of bad memory blocks whether the memory chip is a refresh memory chip or a good memory chip, and upon determining that the memory chip is a refresh memory chip, performing at least one refresh operation on at least one bad memory block of the refresh memory chip.

### CROSS-REFERENCE TO RELATED APPLICATION

This application claims priority under 35 U.S.C. §119 to Korean Patent Application No. 10-2012-0092614 filed on Aug. 23, 2012, the subject matter of which is hereby incorporated by reference.

### BACKGROUND

Certain embodiments of the inventive concept relate to semiconductor memory devices, and more particularly to resistive memory devices capable of performing selective refresh of memory cells. Other embodiments of the inventive concept relate to methods of selectively refreshing memory cells of resistive memory devices.

Semiconductor memory devices may be classified as volatile or nonvolatile according to their operative nature. Volatile semiconductor memory devices, such as dynamic random access memory (DRAM), lose stored data in the absence of applied power but allow relatively fast data access. Such memory devices are used, for example, to configure a main memory in contemporary computers. In contrast, nonvolatile semiconductor memory devices retain stored data in the absence of applied power. Such memory devices are commonly used to store programs and data in a wide variety of applications including consumer electronics, computers, and portable communication devices.

Owing to the demand for fabrication of high-capacity low-power semiconductor memory devices, research has been conducted on advanced nonvolatile memory devices. Currently, phase-change RAMs (PRAMs) using phase-change materials, resistive RAMs (RRAMs) using variable resistive materials, such as transition metal oxides, and magnetic RAMs (MRAMs) using ferromagnetic materials have attracted considerable attention as advanced memory devices. Such advanced memory devices exhibit variable memory cell resistance in accordance with one or more applied control currents and/or voltages. Generally speaking, advanced memory devices do not require the application of periodic refresh operations that characterize DRAM operation, for example. That is, due to the nonvolatile data storage capabilities of advanced memory devices, stored data may be retained over a substantial period of time without the requirement of periodic refresh.

### SUMMARY

In accordance with one aspect of the inventive concept, a method of refreshing a resistive memory device includes; performing a data retention time test on the resistive memory cell array to determine a number of bad memory blocks, determining on the basis of the number of bad memory blocks that the memory chip is a refresh memory chip, and performing at least one refresh operation on at least one bad memory block of the refresh memory chip.

In accordance with another aspect of the inventive concept, a memory system includes; a memory controller including a register, and a resistive memory device including a memory chip having a resistive memory cell array. The memory controller is configured to perform a data retention time test on the resistive memory cell array to determine a number of bad memory blocks and store the number of bad blocks in the register, and is further configured to determine on the basis of the number of bad memory blocks that the memory chip is one of a good memory chip, a refresh memory chip, and a bad memory chip, such that upon determining that the memory chip is a refresh chip the memory controller performs at least one refresh operation on at least one bad memory block of the refresh memory chip.

In accordance with another aspect of the inventive concept, a method of operating a resistive memory device includes; performing a data retention time test on a resistive memory cell array of a memory chip, determining a number of bad memory blocks of the resistive memory cell array on the basis of the data retention time test, determining on the basis of the number of bad memory blocks whether the memory chip is a refresh memory chip or a good memory chip, and upon determining that the memory chip is a refresh memory chip, performing at least one refresh operation on at least one bad memory block of the refresh memory chip.

### BRIEF DESCRIPTION OF THE DRAWINGS

The foregoing and other features and advantages of the inventive concept will be apparent from the more particular description of preferred embodiments of the inventive concept, as illustrated in the accompanying drawings. The drawings are not necessarily to scale, emphasis instead being placed upon illustrating the principles of the inventive concept. In the drawings:

FIG. 1 is a flowchart illustrating a method of refreshing a resistive memory device according to certain embodiments of the inventive concept;

FIG. 2 is a flowchart further illustrating the step of performing a data retention time test on a resistive memory cell array in the method of FIG. 1;

FIG. 3 is a flowchart illustrating a method of counting bad memory blocks based on the result of the data retention time test in the method of FIG. 1;

FIG. 4 is a flowchart further illustrating the step of determining whether the memory chip is a bad chip or a “refresh” chip that should be refreshed using the method of FIG. 1;

FIG. 5 is a conceptual layout diagram illustrating a refresh chip including a plurality of memory blocks;

FIG. 6 is a conceptual layout diagram illustrating a bad chip including a plurality of memory blocks;

FIG. 7 is a block diagram of a resistive memory device in accordance with certain embodiments of the inventive concept;

FIG. 8 is a partial circuit diagram further illustrating the resistive memory cell array of FIG. 7;

FIG. 9 is a circuit diagram illustrating one possible example of a unit memory cell that may be used in the resistive memory cell array of FIG. 8;

FIG. 10 is a diagram illustrating one possible example of a resistive device that may be used in the unit memory cell of FIG. 9;

FIG. 11 is a conceptual diagram illustrating programming of a resistive device in the unit memory cell of FIG. 9;

FIG. 12 is a diagram illustrating another possible example of a resistive device may be used in the unit memory cell of FIG. 9;

FIGS. 13 and 14 are respective diagrams illustrating different magnetization directions for a magnetic tunnel junction (MTJ) element;

FIG. 15 is a conceptual diagram further illustrating a write operation that may be applied to the resistive memory device of FIG. 7;

FIGS. 16, 17, 18, 19 and 20 are respective diagrams of an MTJ element included in a resistive memory cell according to certain embodiments of the inventive concept;

FIGS. 21, 22 and 23 are respective diagrams of memory modules that may be configured to include resistive memory devices according to embodiments of the inventive concept;

FIG. 24 is a perspective view of a semiconductor device having a stacked structure that may be configured to include a resistive memory device according to embodiments of the inventive concept;

FIG. 25 is a block diagram of a memory system that may be configured to include a resistive memory device according to embodiments of the inventive concept;

FIG. 26 is a block diagram of a memory device including a resistive memory device and an optical link according to an embodiment of the inventive concept;

FIGS. 27 and 28 are respective block diagrams of information processing systems including a resistive memory device according to an embodiment of the inventive concept.

### DETAILED DESCRIPTION

Embodiments of the inventive concept will now be described in some additional detail sufficient to enable those of ordinary skill in the art to embody and practice the inventive concept. It is important to understand that the inventive concept may be embodied in many alternate forms and should not be construed as being limited to only the illustrated embodiments.

Accordingly, while the inventive concept is susceptible to various modifications and may take on various alternative forms, specific embodiments thereof are shown by way of example in the drawings and will herein be described in detail. It should be understood, however, that there is no intent to limit the inventive concept to the particular forms disclosed. On the contrary, the inventive concept is to cover all modifications, equivalents, and alternatives falling within the scope of the claims that follow.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the inventive concept.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between,” “adjacent” versus “directly adjacent,” etc.).

The terminology used herein to describe embodiments of the inventive concept is not intended to limit the scope of the inventive concept. The articles “a,” “an,” and “the” are singular in that they have a single referent, however the use of the singular form in the present document should not preclude the presence of more than one referent. In other words, elements of the inventive concept referred to in the singular may number one or more, unless the context clearly indicates otherwise. It will be further understood that the terms “comprises,” “comprising,” “includes,” and/or “including,” when used herein, specify the presence of stated features, items, steps, operations, elements, and/or components, but do not preclude the presence or addition of one or more other features, items, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It should also be noted that in some alternative implementations, the functions/acts noted in the blocks may occur out of the order noted in the flowcharts. For example, two blocks shown in succession may in fact be executed substantially concurrently or the blocks may sometimes be executed in the reverse order, depending upon the functionality/acts involved.

The commercial advantages of resistive memory devices in contemporary consumer electronics, computers, portable devices, etc., has been well established. Yet, as manufacturers of resistive memory devices seek to decrease the size of memory devices or increase memory cell integration density, the nominal size of the constituent unit memory cells decreases. Unfortunately, this overall decrease in resistive memory cell size tends to decreases data storage reliability. That is, a smaller resistive memory cell size tends to decrease the time period over which data may be securely stored. As a result, it has become advantageous if not necessary to provide a refresh operation for resistive memory devices.

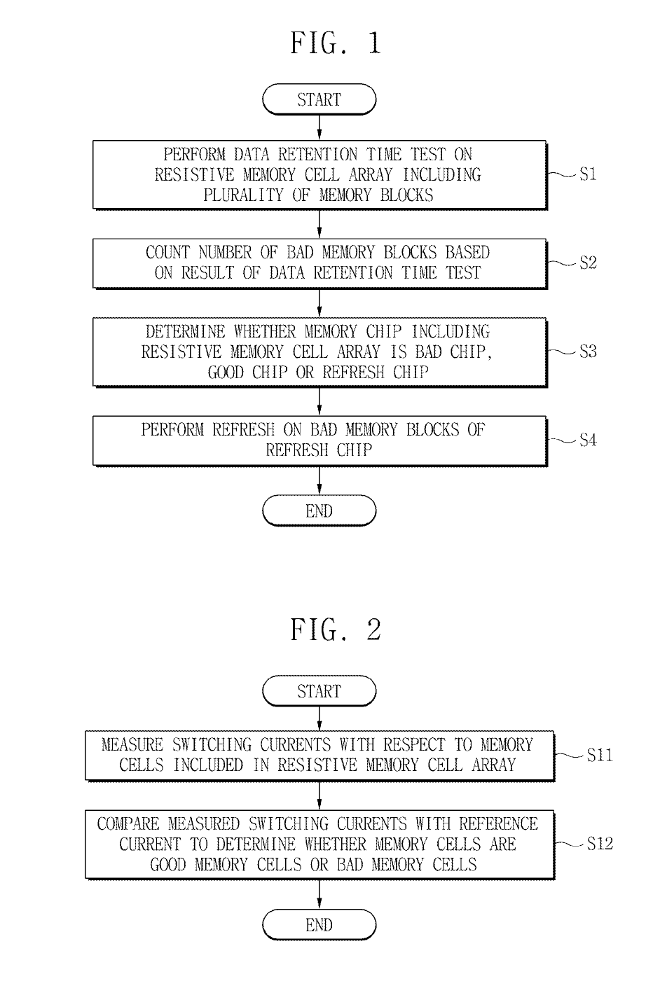

FIG. 1 is a flowchart illustrating a method of refreshing a resistive memory device according to certain embodiments of the inventive concept.

Referring to FIG. 1, the method of refreshing a resistive memory device according to embodiments of the inventive concept generally includes:

(1) performing a data retention time test on a resistive memory cell array—the memory cell array including a plurality of memory blocks (S1);

(2) counting a number of bad memory blocks using the results of the data retention time test (S2);

(3) determining whether each memory chip implementing the resistive memory cell array is a good chip (e.g., a chip having no bad memory blocks), bad chip (e.g., a chip having an excessive number of bad memory blocks), or a refresh chip (e.g., a chip having at least one bad memory block but fewer than a number deemed excessive) (S3); and

(4) performing at least one refresh operation on at least one bad memory block of a refresh chip (S4).

In certain embodiments of the inventive concept, information identifying the number of bad memory blocks and/or the location of bad memory blocks of a memory chip may be stored in one or more registers of a corresponding memory controller. When the number of identified bad memory blocks of a memory chip falls below a first threshold (e.g., a value of 1), the memory chip may be designated as a “good” chip, and refresh operation(s) need not be performed on a good chip. However, when the number of identified bad memory blocks of a memory chip exceeds the first threshold, the memory chip may further be designated as either a “refresh” chip requiring periodic refresh operation(s), or a “bad” (or fail) chip that should not be used to store data.

FIG. 2 is a flowchart further illustrating the step of performing a data retention time test on a resistive memory cell array during the method of FIG. 1.

Referring to FIG. 2, the step of performing the data retention time test on a resistive memory cell array includes:

(1) measuring switching currents with respect to memory cells included in the resistive memory cell array (S11); and

(2) comparing the measured switching currents with a reference current to determine whether the memory cells of the memory chip being tested are good memory cells or bad memory cells (S12).

In certain embodiments of the inventive concept, performing the data retention time test may include measuring (or sampling) the switching currents for a defined number, portion, or percentage of memory cells included in each one of a plurality of memory blocks. For example, the data retention time test may include measuring the switching currents of one in each one thousand of memory cells in a memory block. In certain embodiments of the inventive concept, the data retention time test will be performed on a resistive memory cell during conventionally understood thermal testing (e.g., a baking procedure) on the memory chip.

FIG. 3 is a flowchart further illustrating the step of counting the number of bad memory blocks based on the result of the data retention time test in the method of FIG. 1.

Referring to FIG. 3, the method of counting the number of bad memory blocks may include:

(1) comparing the number of bad memory cells detected among the memory cells included in each memory block with a first reference number (S21);

(2) determining that the memory block as a “good” memory block when the number of bad memory cells in the memory block is less than the first reference number, or a “bad” memory block when the number of bad memory cells in the memory block is greater than or equal to the first reference number (S22); and

(3) counting the number of bad memory blocks (S23).

A bad memory block is one whose performance would markedly benefit from the periodic application of a refresh operation. In certain embodiments of the inventive concept, the first reference number may be a maximum number of memory cells capable of being repaired or compensated for by an available error detection/correction capability (ECC).

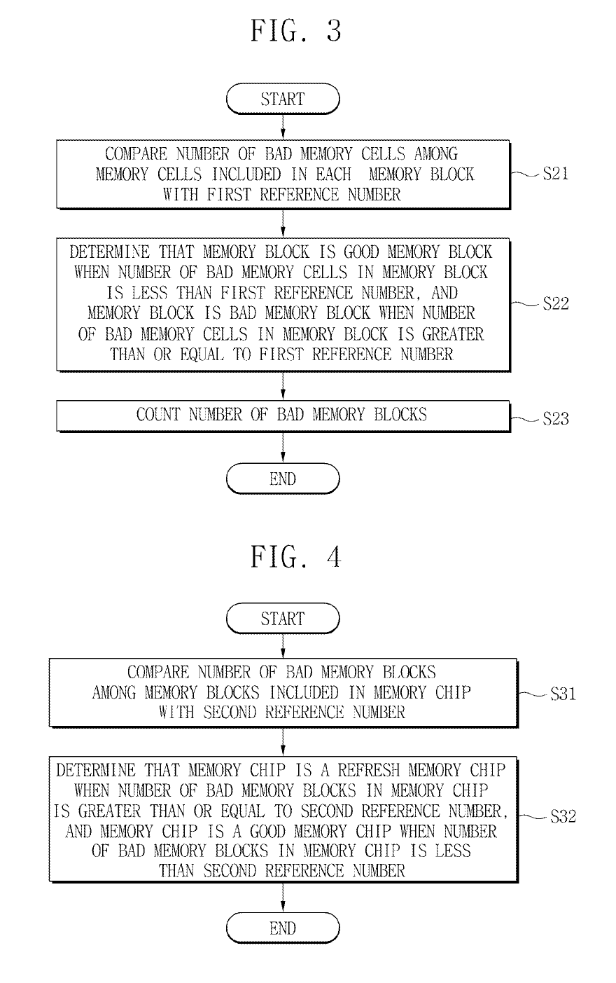

FIG. 4 is a flowchart further illustrating the step of determining whether a memory chip is a good chip or a refresh chip that should be periodically refreshed according to the method of FIG. 1.

Referring to FIG. 4, the method of determining whether the memory chip is a good chip or a refresh chip includes:

(1) comparing the number of identified bad memory blocks among the memory blocks of a memory chip with a second reference number (S31); and

(2) determining that the memory chip is a refresh memory chip when the number of bad memory blocks is greater than or equal to the second reference number, and is a good memory chip when the number of bad memory blocks is less than the second reference number (S32).

In certain embodiments of the inventive concept, the second reference number may be determined based on the specification of a standby current for the resistive memory device.

In similar manner, a determination may be made as to whether the memory chip is a refresh chip or a bad chip.

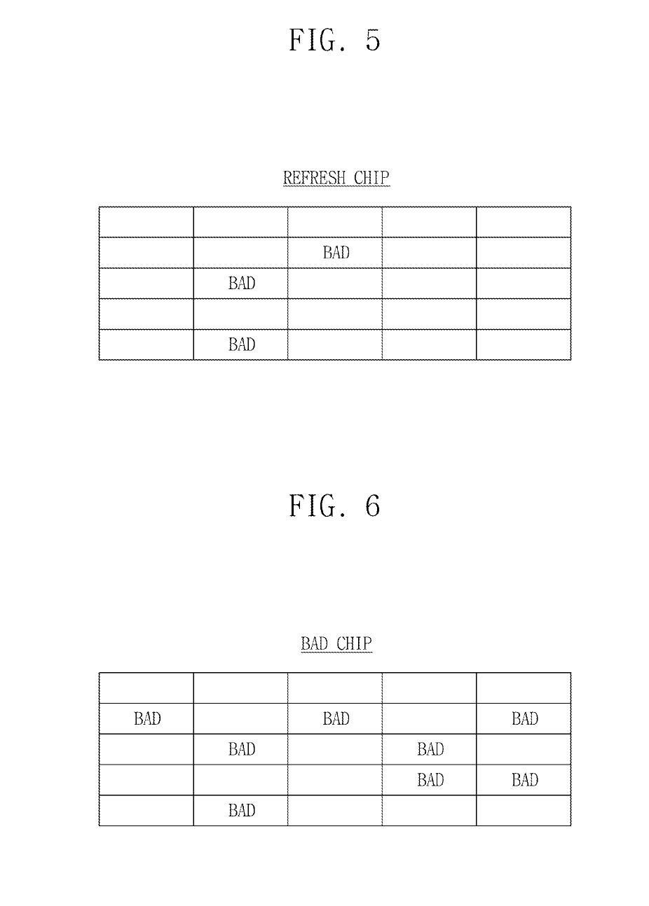

FIG. 5 is a conceptual layout diagram illustrating a refresh memory chip including a plurality of memory blocks, and FIG. 6 is a conceptual layout diagram illustrating a good memory chip including a plurality of memory blocks that is determined as a bad chip.

Referring to FIG. 5, three (3) of twenty-five (25) memory blocks are identified as bad memory blocks, where three (3) is assumed to fall below a given second threshold. Under these conditions, the memory chip is deemed to be a refresh chip. In contrast and referring to FIG. 6, eight (8) of twenty-five (25) memory blocks are identified as bad memory blocks, where eight (8) is assumed to exceed the second threshold. Under these circumstances, the memory chip is deemed to be a bad (or failed) chip.

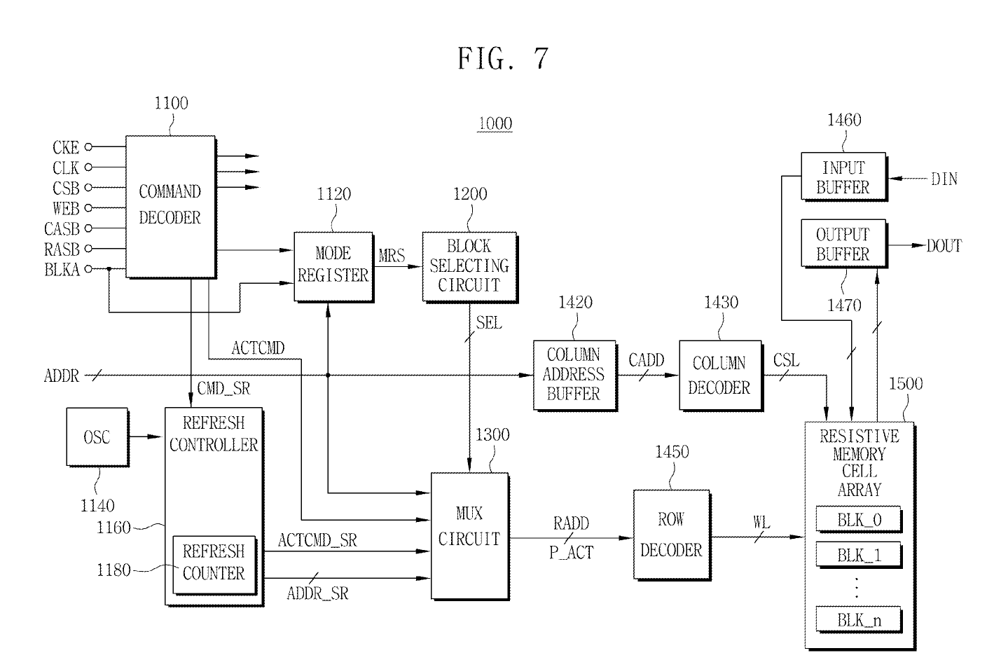

FIG. 7 is a block diagram of a resistive memory device 1000 in accordance with an embodiment of the inventive concept.

Referring to FIG. 7, the resistive memory device 1000 includes a command decoder 1100, a mode register 1120, an oscillator 1140, a refresh controller 1160, a block selecting circuit 1200, a multiplexer circuit 1300, a column address buffer 1420, a column decoder 1430, a row decoder 1450, an input buffer 1460, an output buffer 1470 and a resistive memory cell array 1500. The refresh controller 1160 may include a refresh counter 1180, and the resistive memory cell array 1500 may include a plurality of memory blocks BLK_{—}0, BLK_{—}1, . . . , and BLK_n.

The command decoder 1100 receives a clock enable signal CKE, a clock signal CLK, a chip selecting signal CSB, a write enable signal WEB, a column address strobe signal CASB, a row address strobe signal RASB, and a block address BLKA. The command decoder 1100 generates various commands and control signals necessary for operation of the resistive memory device 1000 based on the write enable signal WEB, the column address strobe signal CASB, and the row address strobe signal RASB.

The mode register 1120 performs programming using the commands, the block address BLKA, and an external address ADDR received from the command decoder 1100, and stores the programmed contents. The oscillator 1140 generates an oscillating signal. The block selecting circuit 1200 receives a mode register signal MRS having information of a memory block on which a refresh operation is to be performed. The block selecting circuit 1200 generates a selection signal SEL based on the mode register signal MRS. The refresh controller 1160 receives a self-refresh command CMD_SR from the command decoder 110, and the oscillating signal from the oscillator 1140. The refresh controller 1160 may include the refresh counter 1180, and generates a self-refresh active command ACTCMD_SR and a self-refresh address ADDR_SR based on the self-refresh command CMD_SR and the oscillating signal.

The multiplexer circuit 1300 selects one of an active command ACTCMD and the self-refresh active command ACTCMD_SR in response to bits of the selection signal SEL, generates a row active signal P_ACT based on the selected command, and selects one of an external address ADDR and the self-refresh address ADDR_SR to generate a row address RADD. The row decoder 1450 decodes the row active signal P_ACT and the row address RADD. The column address buffer 1420 generates a column address CADD based on the external address ADDR. The column decoder 1430 decodes the column address CADD.

The resistive memory device 1000 may store data in the resistive memory cell array 1500, or output data from the resistive memory cell array 1500 based on an output signal of the row decoder 1450 and an output signal of the column decoder 1430. The input buffer 1460 buffers data DIN input to the resistive memory device 1000, and the output buffer 1470 buffers data DOUT output from the resistive memory device 1000.

The resistive memory device 1000 may perform refresh with respect to memory blocks that need to be refreshed among memory blocks included in the resistive memory cell array 1500 based on an output signal of the row decoder 1450.

The semiconductor memory device 1000 of FIG. 7 may include a volatile memory chip such as a dynamic random access memory (DRAM) and a static random access memory (SRAM), a non-volatile memory chip such as a flash memory, a phase change memory, a magnetic random access memory (MRAM), or a resistive random access memory (RRAM), or a combination of thereof.

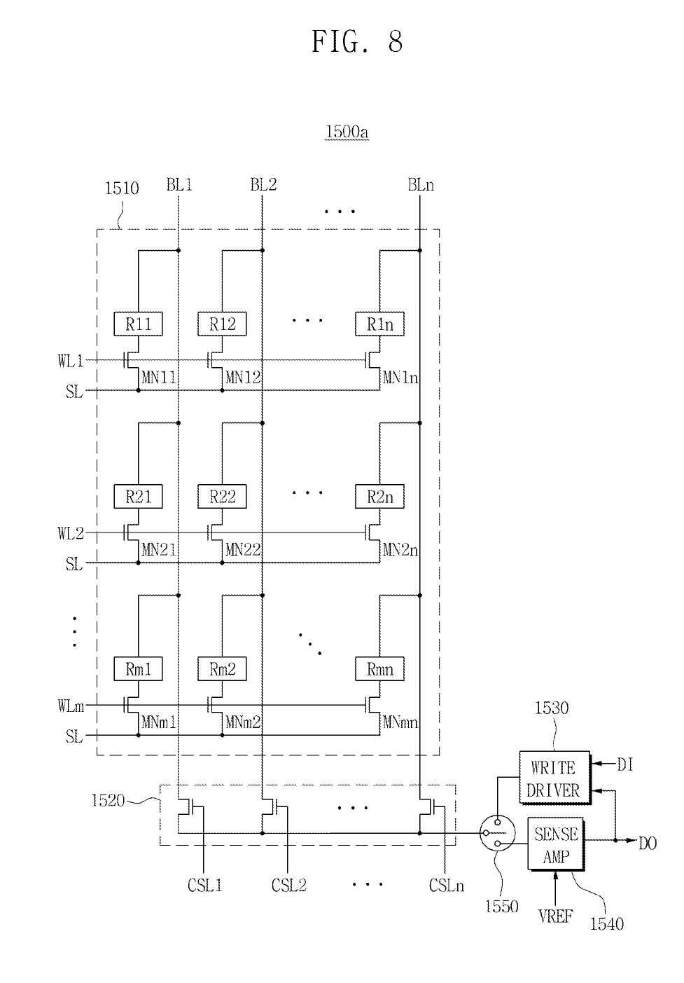

FIG. 8 is a partial circuit diagram of a resistive memory cell array included in the resistive memory device 1000 of FIG. 7.

Referring to FIG. 8, the memory cell array 1500a may include a memory cell array unit 1510, a selection circuit 1520, a sense amplifier 1540, a write driver 1530, and a switch 1550.

The memory cell array unit 1510 may include a plurality of word lines WL1 to WLm and a plurality of bit lines BL1 to BLn, and a unit memory cell may be provided between each of the word lines WL1 to WLm and the corresponding one of the bit lines BL1 to BLn. The selection circuit 1520 may selectively connect the bit lines BL1 to a first node in response to column selection signals CSL1 to CSLn. The sense amplifier 1540 may amplify a difference between the first node and a reference voltage VREF, and generate first data DO. The write driver 1530 may generate a first program current based on write data DI and provide the first program current to the first node during a normal operation. Further, the write driver 1530 may generate a second program current based on the write data DI and provide the second program current to the first node during a test operation. The switch 1550 may selectively connect the first node to the sense amplifier 1540 and the write driver 1530.

The memory cell array unit 1510 may include cell transistors MN11 to MN1n having gates connected to the word line WL1 and resistive devices R11 to R1n respectively connected between the cell transistors MN11 to MN1n and the bit lines BL1 to BLn. Sources of the cell transistors MN11 to MN1n may be connected to the source line SL. Further, the memory cell array unit 1510 may include cell transistors MN21 to MN2n having gates connected to the word line WL2 and resistive devices R21 to R2n respectively connected between the cell transistors MN21 to MN2n and the bit lines BL1 to BLn. Sources of the cell transistors MN21 to MN2n may be connected to the source line SL. Further, the memory cell array unit 1510 may include cell transistors MNm1 to MNmn having gates connected to the word line WLm and resistive devices Rm1 to Rmn respectively connected between the cell transistors MNm1 to MNmn and the bit lines BL1 to BLn. Sources of the cell transistors MNm1 to MNmn may be connected to the source line SL.

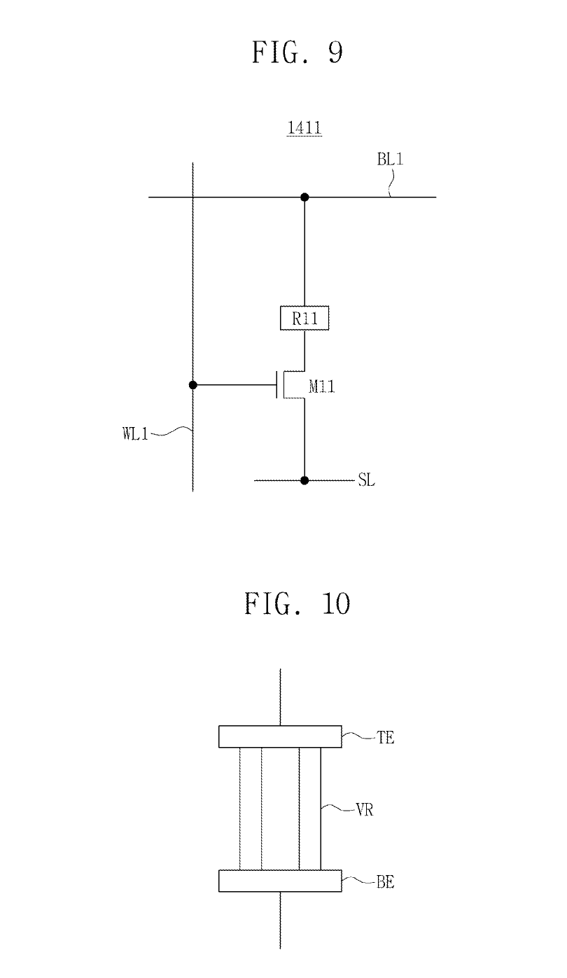

FIG. 9 is a circuit diagram illustrating one possible example of a unit memory cell that may be used in the resistive memory cell array of FIG. 8.

Referring to FIG. 9, a unit memory cell 1411 may include a cell transistor M11 comprised of an NMOS transistor, and a resistive device R11. The cell transistor M11 may have a gate connected to the word line WL1 and a source connected to the source line SL. The resistive device R11 may be connected between the drain of the cell transistor M11 and the bit line BL1.

FIG. 10 is a diagram illustrating another example of a resistive device that may be used as the unit memory cell 1411 of FIG. 9.

Referring to FIG. 10, the resistive device R11 includes a top electrode TE, a bottom electrode BE, and a transition metal oxide VR disposed between the top electrode TE and the bottom electrode BE. Tantalum (Ta) or platinum (Pt) may be used as the top electrode TE and a cobalt oxide may be used as the transition metal oxide VR.

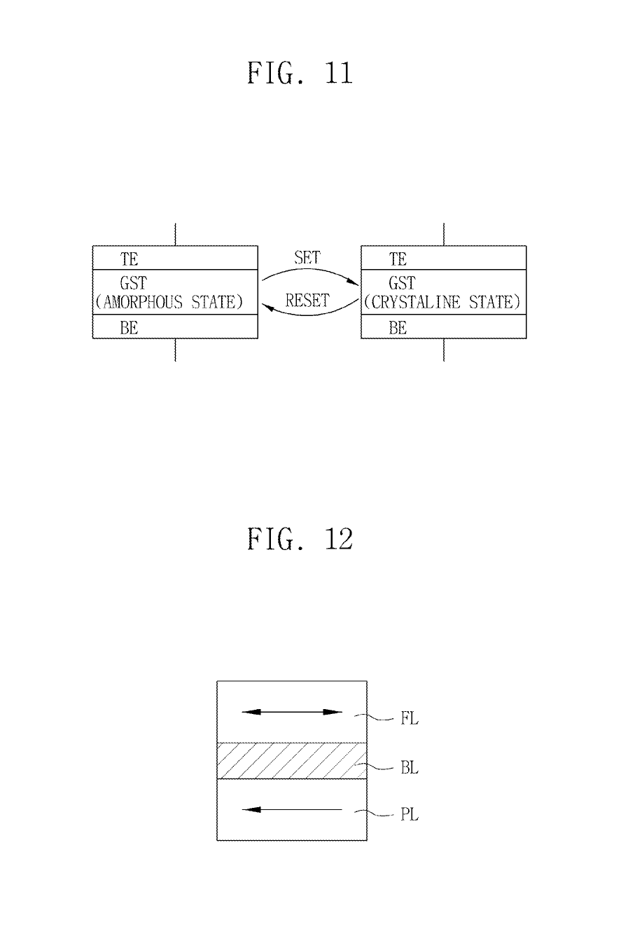

FIG. 11 is a conceptual diagram illustrating programming of a resistive device comprising the unit memory cell of FIG. 9.

Referring to FIG. 11, the resistive device R11 includes a top electrode TE, a bottom electrode BE, and a phase change material (e.g., GST) disposed between the top electrode TE and the bottom electrode BE. The phase change material may be placed in an amorphous state or a crystalline state, such that the resistance of the phase change material is varies in accordance with applied thermal energy (e.g., temperature and heating time). An example of the phase change material or GST may be GeₓSb_{y}Te_{z}.

FIG. 12 is a diagram illustrating still another example of a resistive device comprising the unit memory cell 1411 of FIG. 9.

Referring to FIG. 12, the resistive device R11 may include a pinned layer (PL) having a predetermined pinned magnetization direction, a free layer (FL) magnetized in the direction of an externally applied magnetic field, and a tunnel barrier layer (BL) formed using an insulating film between the pinned layer PL and the free layer FL. To pin the magnetization direction of the pinned layer PL, the resistive device R11 may further include an anti-ferromagnetic layer (not shown). The resistive device R11 of FIG. 12 may be an MTJ element constituting a spin-torque transfer magneto-resistive random access memory (STT-MRAM).

To enable a write operation for the STT-MRAM, the cell transistor MN11 may be turned ON by applying a logic-high voltage to the word line WL1, and a write current may be applied between the bit line BL1 and the source line SL. To enable a read operation for the STT-MRAM, the cell transistor MN11 may be turned ON by applying a logic-high voltage to the word line WL1, and a read current may applied from the bit line BL1 toward a source line SL0 so that data stored in the MTJ cell can be determined according to a measured resistance.

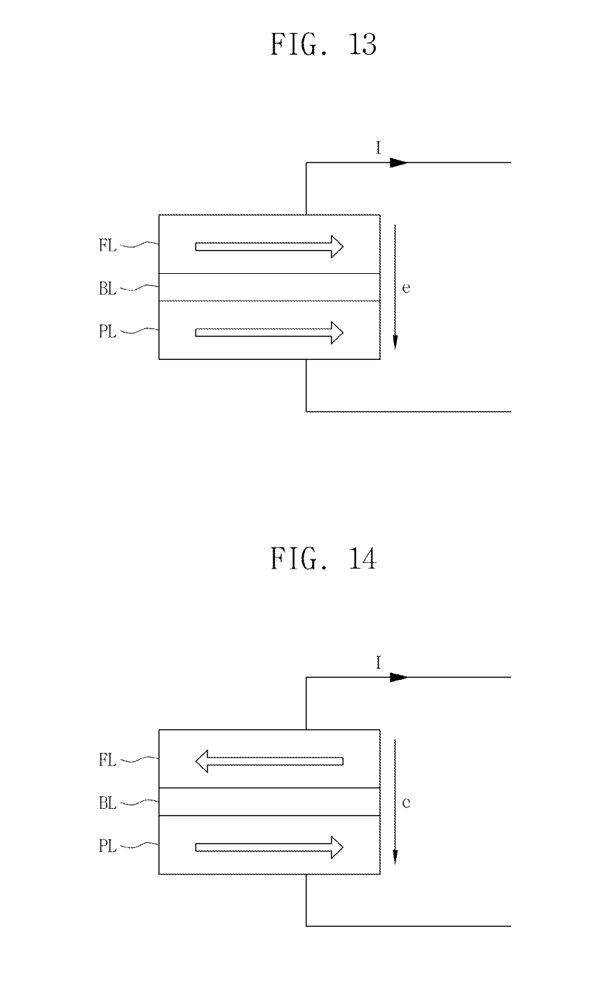

FIGS. 13 and 14 are diagrams illustrating different magnetization directions for an MTJ element according to written data. Resistance of the MTJ element may vary according to a magnetization direction of the free layer FL. When a read current “I” is supplied to the MTJ element, a data voltage may be output according to the resistance of the MTJ element. Since the read current has a much lower intensity than a write current, the magnetization direction of the free layer FL may not be shifted by the read current.

Referring to FIG. 13, in the MTJ element, the magnetization direction of the free layer FL may be parallel to the magnetization direction of the pinned layer PL. Accordingly, the MTJ element may have low resistance. In this case, data ‘0’ may be read.

Referring to FIG. 14, in the MTJ element, magnetization of the free layer FL may be anti-parallel to the magnetization direction of the pinned layer PL. In this case, the MTJ element may have high resistance. In this case, data ‘1’ may be read.

Although FIGS. 13 and 14 illustrate that each of the free layer FL and the pinned layer PL of the MTJ cell is a horizontal magnetic element, the inventive concept may provide other embodiments in which each of the free layer FL and the pinned layer PL is a vertical magnetic element.

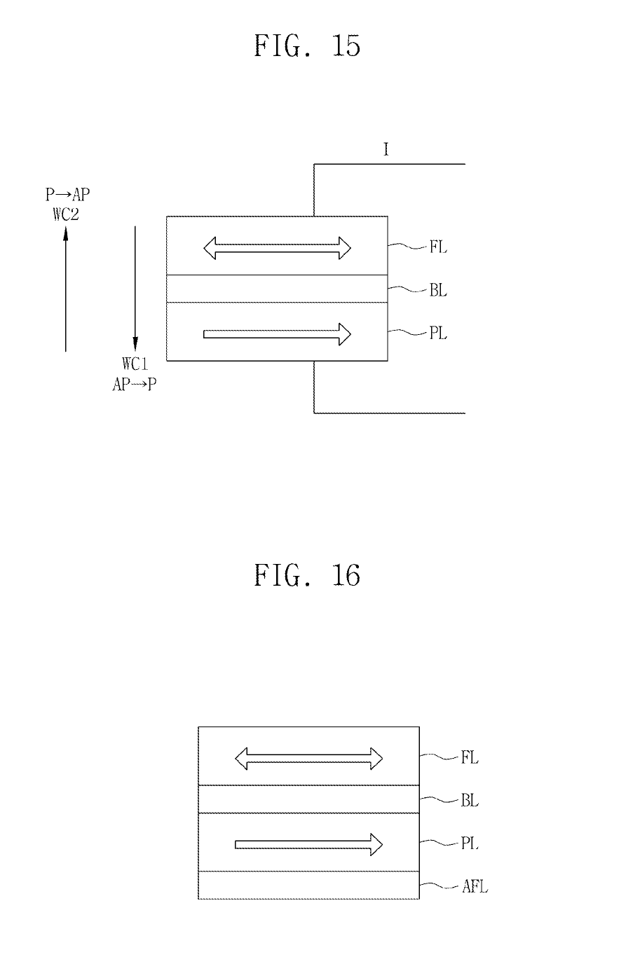

FIG. 15 is a diagram showing a write operation of the resistive memory device of FIG. 7 when a unit memory cell is a resistive memory cell.

Referring to FIG. 15, the magnetization direction of a free layer FL may be determined according to directions of write currents “WC1” and “WC2” flowing through an MTJ element. For instance, when the first write current WC1 is applied, free electrons having the same spin direction as a pinned layer PL may apply torque to the free layer FL. Thus, the free layer FL may be magnetized parallel to the pinned layer PL. When the second write current WC2 is applied, electrons having an opposite spin direction to the pinned layer PL may return to the free layer FL and apply torque. As a result, the free layer FL may be magnetized anti-parallel to the pinned layer PL. That is, in an MTJ cell, the magnetization direction of the free layer FL may be shifted due to spin-transfer torque (STT).

FIGS. 16, 17, 18, 19 and 20 are respective diagrams illustrating an MTJ element included in a resistive memory cell according to various embodiments of the inventive concept.

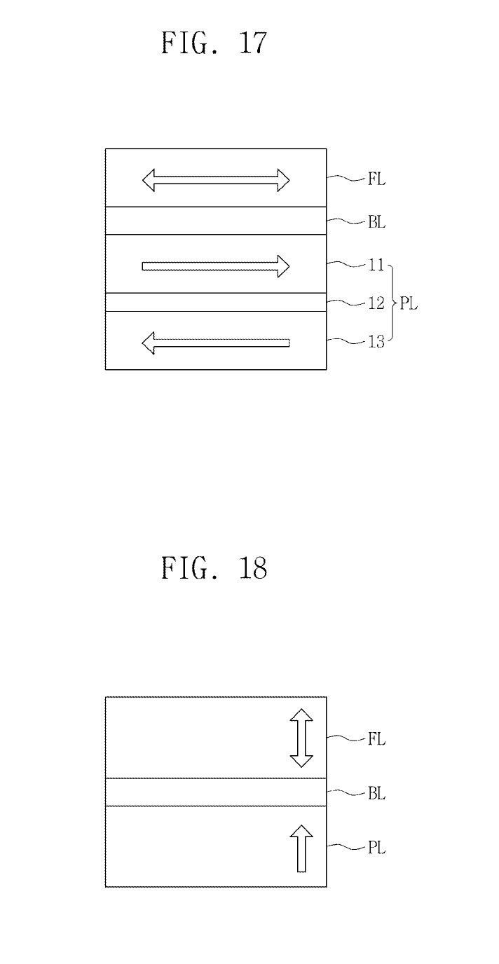

FIGS. 16 and 17 are diagrams of MTJ elements having a horizontal magnetization direction in an STT-MRAM according to embodiments of the inventive concept. An MTJ element having a horizontal magnetization direction refers to an MTJ element in which a direction in which current moves is substantially vertical to a magnetization easy axis.

Referring to FIG. 16, an MTJ element may include a free layer FL, a tunnel bather layer BL, a pinned layer PL, and an anti-ferromagnetic layer (AFL).

The free layer FL may include a material having a changeable magnetization direction. The magnetization direction of the free layer FL may be changed due to electric/magnetic factors provided outside and/or inside a memory cell. The free layer FL may include a ferromagnetic material containing at least one of cobalt (Co), iron (Fe), and nickel (Ni). For instance, the free layer FL may include at least one selected out of FeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, and Y₃Fe₅O₁₂.

The tunnel barrier layer BL may have a thickness smaller than a spin diffusion distance. The tunnel barrier layer BL may include a non-magnetic material. In an example, the tunnel barrier layer BL may include at least one selected out of oxides of magnesium (Mg), titanium (Ti), aluminum (Al), magnesium-zinc (MgZn), and magnesium-boron (MgB) and nitrides of Ti and vanadium (V).

The pinned layer PL may have a magnetization direction pinned by the anti-ferromagnetic layer AFL. Also, the pinned layer PL may include a ferromagnetic material. For example, the pinned layer PL may include at least one selected out of CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, and Y₃Fe₅O₁₂.

The anti-ferromagnetic layer AFL may include an anti-ferromagnetic material. For example, the anti-ferromagnetic layer AFL may include at least one selected out of PtMn, IrMn, MnO, MnS, MnTe, MnF₂, FeCl₂, FeO, CoCl₂, CoO, NiCl₂, NiO, and Cr.

In another embodiment of the inventive concept, since each of a free layer and a pinned layer of an MTJ element is formed of a ferromagnetic material, a stray field may be generated at an edge of the ferromagnetic material. The stray field may reduce magnetoresistance or increase the resistive magnetic force of the free layer and affect switching characteristics, thereby forming asymmetric switching. Accordingly, it is necessary to reduce or control a stray field generated in the ferromagnetic material of the MTJ element.

Referring to FIG. 17, the pinned layer PL of the MTJ element may be formed of a synthetic anti-ferromagnetic (SAF) material. The pinned layer PL may include a first ferromagnetic layer 11, a coupling layer 12, and a second ferromagnetic layer 13. Each of the first and second ferromagnetic layers 11 and 13 may include at least one selected out of CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, and Y₃Fe₅O₁₂. In this case, the magnetization direction of the first ferromagnetic layer 11 may be different from the magnetization direction of the second ferromagnetic layer 13. Each of the magnetization directions of the first and second ferromagnetic layers 11 and 13 may be pinned. The coupling layer 12 may include ruthenium (Ru).

FIG. 18 is a diagram of an MTJ element of an STT-MRAM, according to another embodiment of the inventive concept. In an MTJ element having a vertical magnetization direction, the direction in which current moves may be substantially parallel to a magnetization easy axis. Referring to FIG. 18, the MTJ element may include a free layer FL, a pinned layer PL, and a tunnel barrier layer BL.

When the magnetization direction of the free layer FL is parallel to the magnetization direction of the pinned layer PL, resistance may be reduced. In contrast, when the magnetization direction of the free layer FL is anti-parallel to the magnetization direction of the pinned layer FL, resistance may increase. Different data may be stored according to the resistance.

To embody the MTJ element having the vertical magnetization direction, each of the free layer FL and the pinned layer PL may be formed of a material having a high magnetic isotropic energy. Materials having high magnetic isotropic energies may include an amorphous rare-earth alloy, a multilayered thin layer, such as (Co/Pt)ₙ, or (Fe/Pt)ₙ, or an ordered-lattice material having an L10 crystal structure. For example, the free layer FL may be formed of an ordered alloy and include at least one of iron (Fe), cobalt (Co), nickel (Ni), palladium (Pd), and platinum (Pt). For instance, the free layer FL may include at least one of a Fe—Pt alloy, a Fe—Pd alloy, a Co—Pd alloy, a Co—Pt alloy, a Fe—Ni—Pt alloy, a Co—Fe—Pt alloy, and a Co—Ni—Pt alloy. Chemical quantitative expressions of the above-described alloys may be, for example, Fe₅₀Pt₅₀, Fe₅₀Pd₅₀, Co₅₀Pd₅₀, Co₅₀Pt₅₀, Fe₃₀Ni₂₀Pt₅₀, Co₃₀Fe₂₀Pt₅₀, or Co₃₀Ni₂₀Pt₅₀.

The pinned layer PL may be formed of an ordered alloy and include at least one of Fe, Co, Ni, Pd, and Pt. For example, the pinned layer PL may include at least one of a Fe—Pt alloy, a Fe—Pd alloy, a Co—Pd alloy, a Co—Pt alloy, a Fe—Ni—Pt alloy, a Co—Fe—Pt alloy, and a Co—Ni—Pt alloy. Chemical quantitative expressions of the above-described alloys may be, for example, Fe₅₀Pt₅₀, Fe₅₀Pd₅₀, Co₅₀Pd₅₀, Co₅₀Pt₅₀, Fe₃₀Ni₂₀Pt₅₀, Co₃₀Fe₂₀Pt₅₀, or Co₃₀Ni₂₀Pt₅₀.

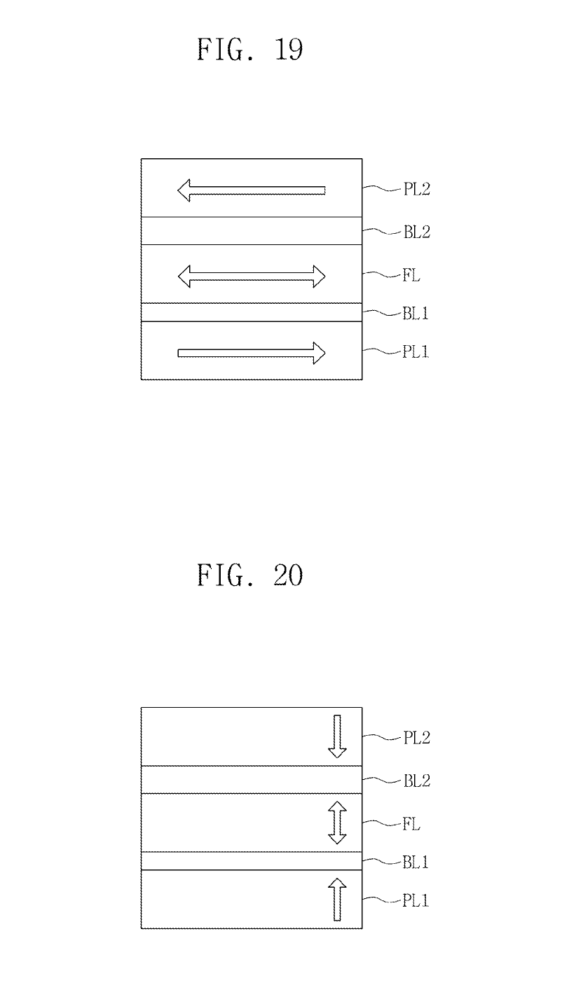

FIGS. 19 and 20 are diagrams of dual MTJ elements, which are MTJ elements included in STT-MRAMs according to embodiments of the inventive concept. A dual MTJ element may be configured such that a tunnel barrier layer and a pinned layer are respectively disposed on both ends of a free layer.

Referring to FIG. 19, a dual MTJ element configured to form a horizontal magnetic field may include a first pinned layer PL2, a first tunnel barrier layer BL2, a free layer FL, a second tunnel barrier layer BL1, and a second pinned layer PL1. Each of the first pinned layer PL2, the first tunnel barrier layer BL2, the free layer FL, the second tunnel barrier layer BL1, and the second pinned layer PL1 may include the same material as or similar materials to the corresponding one of the free layer FL, the tunnel barrier layer BL, and the pinned layer PL of FIG. 8.

In this case, when the first pinned layer PL2 is pinned in an opposite magnetization direction to the second pinned layer PL1, magnetic forces caused by the first and second pinned layers PL2 and PL1 may substantially counteract each other. Accordingly, the dual MTJ element may enable a write operation using a smaller current than a typical MTJ element.

In addition, since the dual MTJ element provides a higher resistance during a read operation due to the second tunnel barrier layer BL1, clear data may be obtained.

Referring to FIG. 20, a dual MTJ element configured to form a vertical magnetic field may include a first pinned layer PL2, a first tunnel barrier layer BL2, a free layer FL, a second tunnel barrier layer BL1, and a second pinned layer PL1. Each of the first pinned layer PL2, the first tunnel barrier layer BL2, the free layer FL, the second tunnel barrier layer BL1, and the second pinned layer PL1 may include the same material as or similar materials to the corresponding one of the free layer FL, the tunnel barrier layer BL, and the pinned layer PL of FIG. 12.

In this case, when the first pinned layer P is pinned in an opposite magnetization direction to the second pinned layer P, magnetic forces caused by the first and second pinned layers P and P may substantially counteract each other. Accordingly, the dual MTJ element may enable a write operation using a smaller current than a typical MTJ element.

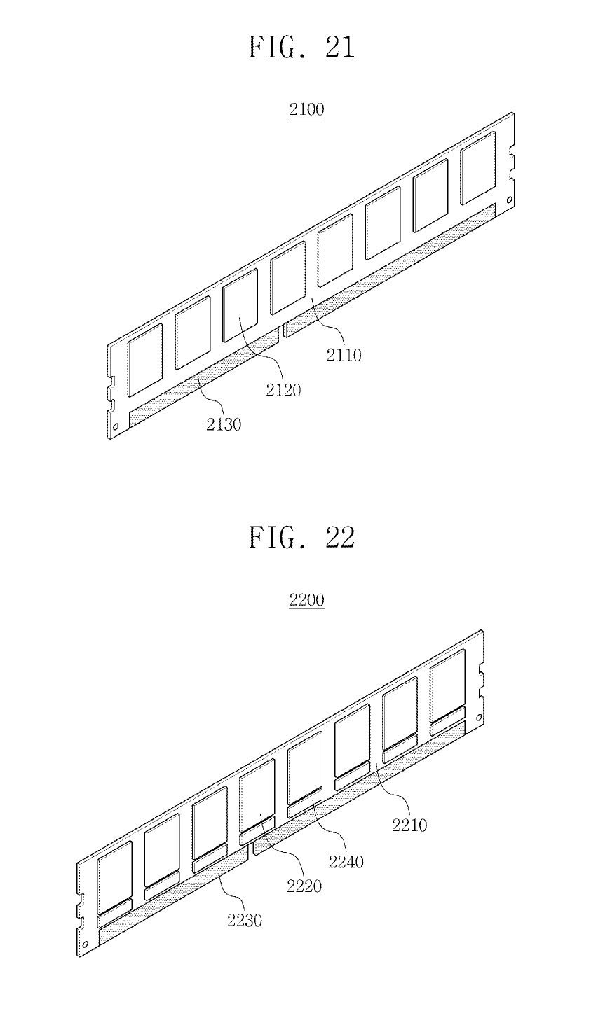

FIGS. 21, 22 and 23 are respective diagrams of memory modules 2100, 2200, and 2300 that may be configured to include MRAM devices according to one or more embodiment(s) of the inventive concept.

Referring to FIG. 21, the memory module 2100 may include a printed circuit board (PCB) 2110, a plurality of MRAM chips 2120, and a connector 2130. The plurality of MRAM chips 2120 may be bonded to top and bottom surfaces of the PCB 2110. The connector 2130 may be electrically connected to the plurality of MRAM chips 2120 through conductive lines (not shown). Also, the connector 2130 may be connected to a slot of an external host.

Referring to FIG. 22, the memory module 2200 may include a PCB 2210, a plurality of MRAM chips 2220, a connector 2230, and a plurality of buffers 2240. Each of the plurality of buffers 2240 may be disposed between the corresponding one of the MRAM chips 2220 and the connector 2230.

The MRAM chips 2220 and the buffers 2240 may be provided on top and bottom surfaces of the PCB 2210. The MRAM chips 2220 and the buffers 2240 formed on the top and bottom surfaces of the PCB 2210 may be connected through a plurality of via holes.

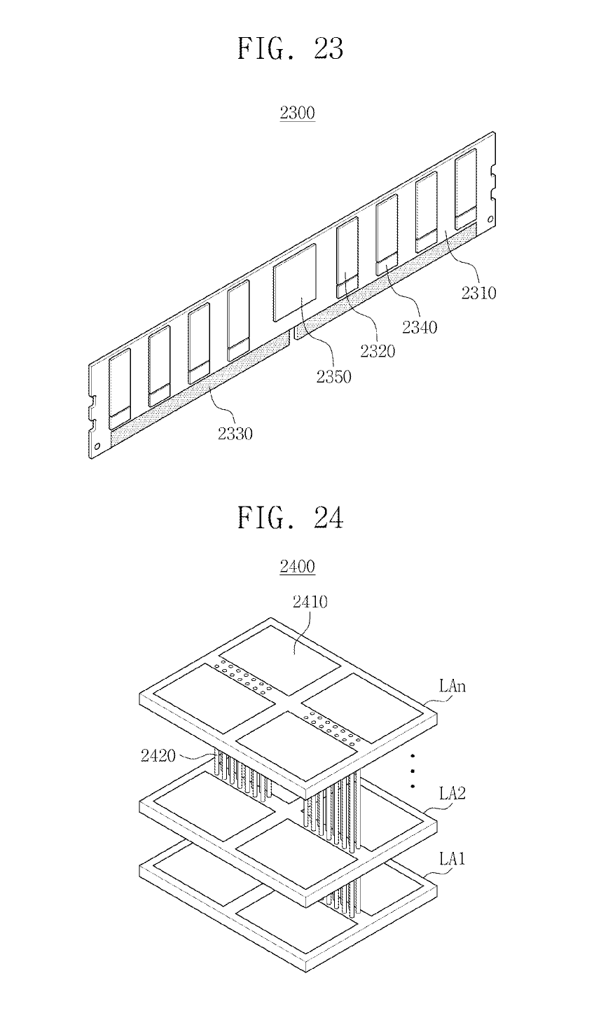

Referring to FIG. 23, the memory module 2300 may include a PCB 2310, a plurality of MRAM chips 2320, a connector 2330, a plurality of buffers 2340, and a controller 2350.

The MRAM chips 2320 and the buffers 2340 may be provided on top and bottom surfaces of the PCB 2310. The MRAM chips 2320 and the buffers 2340 formed on the top and bottom surfaces of the PCB 2310 may be connected through a plurality of via holes.

FIG. 24 is a perspective view of a stacked semiconductor device 2400 including a plurality of semiconductor layers according to an embodiment of the inventive concept. In the memory modules 2100, 2200, and 2300 of FIGS. 21 through 23, each of the MRAM chips 2120, 2220, and 2320 may include a plurality of semiconductor layers LA1 to LAn.

In the stacked semiconductor device 2400, the plurality of stacked semiconductor layers LA1 to LAn may be connected to one another through through-silicon vias (TSVs) 2420. Each of the semiconductor layers LA1 to LAn may include cell arrays 2410 including STT-MRAM cells.

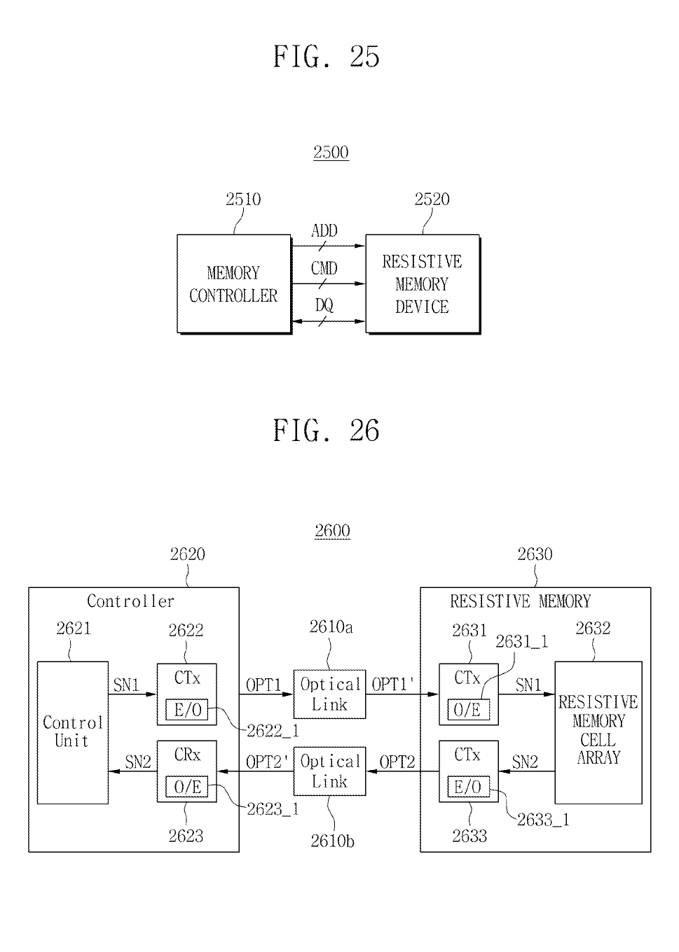

FIG. 25 is a block diagram of a memory system 2500 that may be configured to incorporate a resistive memory device 2520 according to an embodiment of the inventive concept.

Referring to FIG. 25, the memory system 2500 may include a memory controller 4510 and a resistive memory device 2520.

The memory controller 2510 may generate an address signal ADD and a command CMD, and provide the address signal ADD and the command CMD to the resistive memory device 2520 through buses. Data DQ may be transmitted from the memory controller 2510 to the resistive memory device 2520 through the buses, or transmitted from the resistive memory device 2520 to the memory controller 2510 through the buses.

The resistive memory device 2520 may be a resistive memory device 1000 according to an embodiment of the inventive concept.

FIG. 26 is a block diagram of a memory system 2600 that may be configured to incorporate a resistive memory device and an optical link according to an embodiment of the inventive concept.

Referring to FIG. 26, the memory system 2600 may include a controller 2620, a resistive memory device 2630, and a plurality of optical links 2610a and 2610b configured to interconnect the controller 2620 and the resistive memory device 2630. The controller 2620 may include a control unit 2621, a first transmitter 2622, and a first receiver 2623. The control unit 2621 may transmit a control signal SN1 to the first transmitter 2622.

The first transmitter 2622 may include a first optical modulator 2622_{—}1, which may convert the control signal SN1, which is an electric signal, into a first optical transmission signal OPT1, and transmit the first optical transmission signal OPT1 to the optical link 2610a.

The first receiver 2623 may include a first optical demodulator 2623_{—}1, which may convert a second optical receiving signal OPT2′ received from the optical link 2610b into a data signal SN2, which is an electric signal, and transmit the data signal SN2 to the control unit 2621.

The resistive memory device 2630 may include a second receiver 2631, a resistive memory cell array 2632, and a second transmitter 2633. The second receiver 2631 may include a second optical modulator 2631_{—}1, which may convert a first optical receiving signal OPT1′ received from the optical link 2610a into the control signal SN1, which is the electric signal, and transmit the control signal SN1 to the resistive memory cell array 2632.

In the resistive memory cell array 2632, data may be written under the control of the control signal SN1, or the data signal SN2 output by the resistive memory cell array 2632 may be transmitted to the second transmitter 2633.

The second transmitter 2633 may include a second optical modulator 2633_{—}1, which may convert the data signal SN2, which is the electric signal, into a second optical data signal OPT2, and transmit the second optical data signal OPT2 to the optical link 2610b.

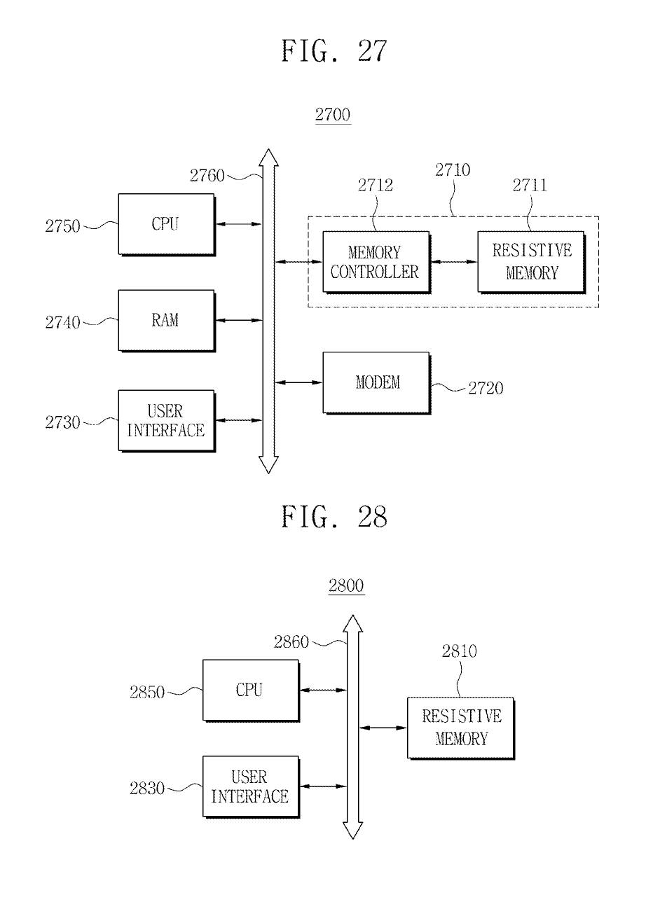

FIG. 27 is a block diagram of an information processing system including a resistive memory device according to an embodiment of the inventive concept.

Referring to FIG. 27, a resistive memory device 2711 may be mounted in a computer system, such as a mobile device or a desktop computer. The information processing system 2700 may include a memory system 2710, a modem 2720, a central processing unit (CPU) 2750, a RAM 2740, and a user interface 2730, which may be electrically connected to a system bus 2760.

The memory system 2710 may include the resistive memory device 2711 and a memory controller 2712. Data processed by the CPU 2750 or externally input data may be stored in the resistive memory device 2711.

At least one of the resistive memory device 2711 or the RAM 2740 may be applied to a semiconductor memory device including STT-MRAM cells. That is, a semiconductor memory device including STT-MRAM cells may be applied to the MRAM device 2711 configured to store a large capacity of data required for the information processing system 2700, or the RAM 2740 configured to store data (i.e., system data) that needs to be rapidly accessed. Although not shown in FIG. 27, it would be apparent to those of ordinary skill in the art that an application chipset, a camera image processor (CIP), and an input/output (I/O) device may be further provided in the information processing system 2700.

FIG. 28 is a block diagram of another information processing system including a resistive memory device according to an embodiment of the inventive concept.

Referring to FIG. 28, a resistive memory device 2810 including STT-MRAM cells may be mounted in a computer system 2800, such as a mobile device or a desktop computer. The computer system 2800 may include an MRAM device 2810, a CPU 2850, and a user interface 2830, which may be electrically connected to a system bus 2860.

Among resistive memory devices, the STT-MRAM may be understood as an advanced memory that satisfies the coincident demands of low-cost, large-capacity data storage characteristics like a DRAM, fast operating speed like a static RAM (SRAM), and the non-volatile data storage characteristics of flash memory. Accordingly, while a conventional system requires an additional cache memory for high speed data processing and additional mass storage (e.g., a RAM) configured to store a large capacity of data, the cache memory and the mass storage may be replaced by an MRAM device according to an embodiment of the inventive concept. That is, since a memory device including an MRAM may rapidly store a large capacity of data, a computer system may be configured more simply than in the conventional art.

A method of refreshing a resistive memory device according to embodiments may include performing a data retention time test for a resistive memory cell array including a plurality of memory blocks; counting the number of bad memory blocks based on the result of the data retention time test; determining whether a memory chip including the resistive memory cell array is a good chip, a refresh chip, or a bad chip based on the number of bad memory blocks; and performing at least one refresh operation on at least one bad memory blocks of a refresh memory chip.

Accordingly, since the resistive memory device including an STT-MRAM according to embodiments can selectively perform refresh on the memory cells included in a memory cell array, a reliability of the resistive memory device can be improved.

The inventive concept may be applied to a semiconductor device, particularly, a resistive memory device and a memory system including the same.

The foregoing is illustrative of embodiments and is not to be construed as limiting thereof. Although a few embodiments have been described, those skilled in the art will readily appreciate that many modifications are possible without materially departing from the novel teachings and advantages. Accordingly, all such modifications are intended to fall within the scope of this inventive concept as defined in the claims.

What is claimed is:

1. A method of refreshing a resistive memory device comprising a memory chip having a resistive memory cell array, the method comprising:
performing a data retention time test on the resistive memory cell array to determine a number of bad memory blocks;
determining on the basis of the number of bad memory blocks that the memory chip is a refresh memory chip; and
performing at least one refresh operation on at least one bad memory block of the refresh memory chip.

2. The method of claim 1, wherein performing the data retention time test comprises:
measuring switching currents for selected resistive memory cells of the memory cell array; and
comparing the measured switching currents with a reference current to determine whether each one of the selected resistive memory cells is a good memory cell or bad memory cell.

3. The method of claim 1, wherein the data retention time test is performed on a memory block by memory block basis for a plurality of memory blocks implementing the resistive memory cell array.

4. The method of claim 3, wherein performing the data retention time test comprises measuring switching currents for selected resistive memory cells across the plurality of memory blocks.

5. The method of claim 1, wherein the data retention time test is performed during thermal testing of the memory chip.

6. The method of claim 1, wherein performing the data retention time test on the resistive memory cell array to determine the number of bad memory blocks comprises:
for each memory block among a plurality of memory block of the resistive memory cell array, comparing a number of bad memory cells identified in the memory block with a first reference number, and if the number of bad memory cells exceeds the first reference number designating the memory block as a bad memory block.

7. The method of claim 6, further comprising:
if the number of bad memory cells does not exceed the first reference number designating the memory block as a good memory block.

8. The method of claim 6, wherein the first reference number is a maximum number of memory cells repairable by an error detection/correction capability (ECC) of the resistive memory device.

9. The method of claim 1, further comprising:
determining on the basis of the number of bad memory blocks that the memory chip is a good memory chip, and upon determining that the memory chip is a good memory chip, performing no refresh operation on any memory block of the good memory chip.

10. The method of claim 9, further comprising:
determining on the basis of the number of bad memory blocks that the memory chip is a bad memory chip.

11. The method of claim 10, wherein a first reference number compared with the number of bad memory blocks is used to distinguish a good memory chip from a refresh memory chip, and a second reference number greater than the first reference number compared with the number of bad memory block is used to distinguish a refresh memory chip from a bad memory chip.

12. A memory system comprising:
a memory controller including a register; and
a resistive memory device including a memory chip having a resistive memory cell array,
wherein the memory controller is configured to perform a data retention time test on the resistive memory cell array to determine a number of bad memory blocks and store the number of bad blocks in the register, and
the memory controller is further configured to determine on the basis of the number of bad memory blocks that the memory chip is one of a good memory chip, a refresh memory chip, and a bad memory chip, such that upon determining that the memory chip is a refresh chip the memory controller performs at least one refresh operation on at least one bad memory block of the refresh memory chip.

13. The memory system of claim 12, wherein each resistive memory cell of the resistive memory cell array comprises:
a free layer of a first ferromagnetic material;
a pinned layer of a second ferromagnetic material; and
a tunnel barrier layer disposed between the free layer and the pinned layer.

14. The device of claim 12, wherein each resistive memory cell of the resistive memory cell array is a spin-transfer-torque magneto-resistive random access memory (STT-MRAM).

15. A method of operating a resistive memory device, the method comprising:
performing a data retention time test on a resistive memory cell array of a memory chip;
determining a number of bad memory blocks of the resistive memory cell array on the basis of the data retention time test;
determining on the basis of the number of bad memory blocks whether the memory chip is a refresh memory chip or a good memory chip; and
upon determining that the memory chip is a refresh memory chip, performing at least one refresh operation on at least one bad memory block of the refresh memory chip.

16. The method of claim 15, wherein performing the data retention time test comprises:
measuring switching currents for selected resistive memory cells of the memory cell array; and
comparing the measured switching currents with a reference current to determine whether each one of the selected resistive memory cells is a good memory cell or bad memory cell.

17. The method of claim 15, wherein the data retention time test is performed on a memory block by memory block basis for a plurality of memory blocks implementing the resistive memory cell array.

18. The method of claim 17, wherein performing the data retention time test comprises measuring switching currents for selected resistive memory cells across the plurality of memory blocks.

19. The method of claim 15, wherein the data retention time test is performed during thermal testing of the memory chip.

20. The method of claim 15, wherein each resistive memory cell of the resistive memory cell array is a spin-transfer-torque magneto-resistive random access memory (STT-MRAM).
